(19) United States
(12) Patent Application Publication
(10) Pub. No.: US 2017/0342562 A1
(43) Pub. Date: Nov. 30, 2017

(54) VAPOR MANIFOLD WITH INTEGRATED VAPOR CONCENTRATION SENSOR

(71) Applicant: Lam Research Corporation, Fremont, CA (US)

(72) Inventors: Gary Bridger Lind, Penn Valley, CA (US); Panya Wongsenakhum, Santa Clara, CA (US); Eric H. Lenz, Livermore, CA (US); Joshua Collins, Sunnyvale, CA (US)

(21) Appl. No.: 15/169,582

(22) Filed: May 31, 2016

(51) Int. Cl. C23C 16/455; H01L 21/67

(52) U.S. Cl. CPC C23C 16/45544; H01L 21/67063; H01L 21/67242

(57) ABSTRACT

Vapor accumulator reservoirs for semiconductor processing operations, such as atomic layer deposition operations, are provided. Such vapor accumulator reservoirs may include an optical beam port to allow an optical beam to transit through the vapor and allow measurement of the vapor concentration in the reservoir. In some implementations, the reservoir may be integrated with a vacuum pumping manifold and the reservoir and manifold may be heated by a common heating system to prevent condensation of the vapor.

### BACKGROUND

During semiconductor processing operations, one or more reactants may be distributed across a semiconductor wafer in order to perform etching, deposition, cleaning, or other operations. In some such semiconductor operations, the reactant or reactants may be provided in a vaporized form that is suspended in a carrier gas, e.g., a gas that may be chemically inert or non-reactive with respect to the other reactants used, before being flowed across the semiconductor wafer.

Some semiconductor processing operations, such as atomic layer deposition (ALD) or atomic layer etching (ALE) may involve applying very short flows of two or more different reactants in an alternating fashion across a semiconductor wafer. The reactants, which may also be referred to as precursors herein, used in such semiconductor processing operations may exhibit a chemically self-limiting reaction with the semiconductor wafer under certain circumstances. For example, a first reactant may be flowed across the semiconductor wafer. The first reactant may prepare the surface of the semiconductor wafer so as to have a certain receptivity to reacting with a second, different reactant. The first reactant flow may be stopped and the remaining first reactant purged by flowing a purge gas through the reaction chamber, and the second reactant may then be flowed across the semiconductor wafer, where it may react with the prepared surface, thereby producing a single-molecule thick deposition layer or removing a single-molecule layer of material. The flow of the second reactant may then be stopped and a further purge cycle may be performed to remove the second reactant from the reaction chamber. This sequential flow of multiple different reactants, punctuated by purge gas flows, may be referred to as a “cycle,” e.g., an ALD cycle or an ALE cycle. A typical ALD or ALE cycle may have a total duration on the order of less than a second to several seconds, e.g., 2-3 seconds, and hundreds or thousands of such cycles may need to be performed to achieve a desired layer thickness or etch removal amount since each cycle may only affect a sub-layer that is one molecule thick.

### BRIEF DESCRIPTION OF THE DRAWINGS

The accompanying drawings are illustrative and the concepts discussed herein are not limited to only the depicted implementations.

FIG. 1 depicts a high-level schematic of a semiconductor processing tool that incorporates a vapor accumulator reservoir.

FIG. 2 depicts an example of a vapor accumulator reservoir as discussed herein.

FIG. 3 depicts the vapor accumulator reservoir of FIG. 2 as it may be positioned in a semiconductor processing tool, although with most of the heating jacket and various other components absent.

FIG. 4 depicts another view of the apparatus 201.

FIG. 5 depicts a cutaway view of the apparatus 201.

FIG. 6 depicts another cutaway view of the apparatus 201.

FIG. 7 depicts a further cutaway of the apparatus 201.

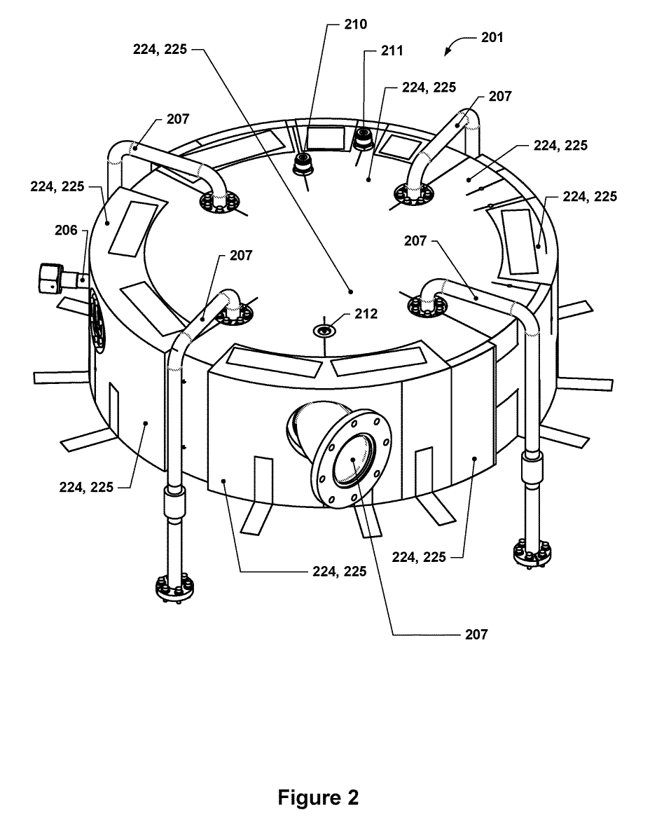

FIGS. 2 through 7 are to-scale within each Figure, although the Figures may not be to-scale with each other.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus for use in a semiconductor processing tool may be provided. The apparatus may include a vapor accumulator reservoir having a vapor accumulation volume, a vapor inlet in fluidic communication with the vapor accumulation volume, one or more vapor outlets, a first optical beam port, and an optical vapor concentration sensor. Each vapor outlet may be in fluidic communication with the vapor accumulation volume. The first optical beam port may provide an optical path into the vapor accumulation volume and the optical vapor concentration sensor may be configured to direct a beam of light through the first optical beam port and through the vapor accumulation volume.

In some such implementations, the apparatus may further include a second optical beam port located on an opposite side of the vapor accumulator reservoir from the first optical beam port. The optical vapor concentration sensor may include a beam emitter positioned so as to project the beam of light through the first optical beam port and a photosensor positioned so as to receive the beam of light via the second optical beam port.

In some implementations of the apparatus, the optical vapor concentration sensor may be configured to produce a beam of light that is predominantly comprised of light in the ultraviolet spectrum.

In some implementations of the apparatus, the apparatus may further include one or more vaporizers in fluidic communication with the vapor inlet and a sonic flow orifice interposed between the vapor inlet and the one or more vaporizers. In such implementations, the sonic flow orifice may be sized so as to develop choked flow during semiconductor processing operations performed using the apparatus.

In some implementations of the apparatus, the apparatus may further include a dilution gas inlet that is configured to be connected with a chemically inert dilution gas source.

In some implementations of the apparatus, the apparatus may further include a vacuum pumping manifold that includes a vacuum pumping plenum volume that at least partially encircles the majority of the vapor accumulation volume. Such an apparatus may further include one or more vacuum inlet ports, each vacuum inlet port in fluidic communication with the vacuum pumping plenum volume, and a vacuum output port, the vacuum outlet port in fluidic communication with the vacuum pumping plenum volume.

In some such implementations of the apparatus, the vacuum pumping plenum volume may be defined, at least in part, by an inner wall and an outer wall, and the vapor accumulation plenum volume may be defined, at least in part, by the inner wall.

In some further such implementations of the apparatus, the vapor accumulator reservoir may be cylindrical in overall shape and the vacuum pumping manifold may be annular in overall shape.

In some implementations of the apparatus, there may be four vacuum inlet ports forming a first set of two vacuum inlet ports and a second set of two vacuum inlet ports, the vacuum pumping manifold may have an annular partition wall that divides the vacuum pumping plenum volume into an upper annular pumping plenum volume and a lower annular pumping plenum volume, the annular partition wall may be interposed between the vacuum outlet port and the vacuum inlet ports, the annular partition wall may include two sets of one or more partition openings, each set of one or more partition openings may be located equidistant from the vacuum outlet port, each vacuum inlet port in the first set of inlet vacuum ports may be located equidistant from one of the sets of one or more partition openings, and each vacuum inlet port in the second set of inlet vacuum ports may be located equidistant from the other set of one or more partition openings.

In some implementations of the apparatus, the apparatus may further include a heating jacket that includes one or more portions adjacent to an upper wall of the vapor accumulator reservoir, one or more portions adjacent to a lower wall of the vapor accumulator reservoir, one or more portions adjacent to an upper wall of the vacuum pumping manifold, one or more portions adjacent to a lower wall of the vacuum pumping manifold, and one or more portions adjacent to an outer wall of the vacuum pumping manifold, wherein each of the portions include one or more heating elements configured to supply heat to the wall to which that portion is adjacent.

In some implementations, the apparatus may further include a first optical tunnel that terminates at the first optical beam port, extends through the vacuum pumping plenum volume, is part of the vapor accumulator reservoir, and is in fluidic communication with the vapor accumulation volume.

In some further such implementations, the apparatus may also include a second optical beam port located on an opposite side of the vapor accumulator reservoir from the first optical beam port and a second optical tunnel that terminates at the second optical beam port, extends through the vacuum pumping plenum volume, is part of the vapor accumulator reservoir, and is in fluidic communication with the vapor accumulation volume. In such implementations, the optical vapor concentration sensor may include a beam emitter positioned so as to project the beam of light through the first optical beam port and a photosensor positioned so as to receive the beam of light via the second optical beam port.

In some implementations of the apparatus, the apparatus may also include one or more semiconductor processing chambers, each semiconductor processing chamber including a control valve assembly in fluidic communication with one of the vapor outlets. In such implementations, the control valve assembly for each semiconductor processing chamber may be configured to regulate vapor flow from the vapor accumulation volume to that semiconductor processing chamber via one of the vapor outlets.

In some implementations of the apparatus, the apparatus may further include a carrier gas source and one or more ampoules, each ampoule including a solid or liquid precursor and in fluidic communication with the vapor inlet. In such implementations, the carrier gas source may be configured to flow carrier gas through each of the one or more ampoules and into the vapor inlet.

In some further or alternative such implementations, each of the one or more semiconductor processing chambers may be configured for atomic layer deposition and may have a microvolume that is formed between a pedestal of that semiconductor processing chamber and a gas distributor of that semiconductor processing chamber during wafer processing operations. In such implementations, the vapor accumulation volume may have a volume Vp that satisfies the relationship:

$${V}_{p} > \frac{100 {nP}_{c} {V}_{m} q}{20 ( {P}_{p} - {P}_{c} )}$$

where: n=number of semiconductor processing chambers served by the vapor accumulator reservoir, Pc=average chamber pressure in the microvolumes of those semiconductor processing chambers during atomic layer deposition operations, Vm=microvolume volume for each of those semiconductor processing chambers, q=the number of microvolumes' worth of vapor delivered to one of the processing chambers' microvolume during a single vapor dose, and Pp=peak pressure in the vapor accumulator reservoir during delivery of a vapor dose to one of the microvolumes.

In some such implementations, the apparatus may further include a sonic flow orifice located on the vapor inlet and sized such that fully choked flow develops through the sonic flow orifice during all phases of atomic layer deposition operations in the one or more semiconductor processing chambers.

In some implementations of the apparatus, there may be multiple semiconductor processing chambers and the vapor accumulation volume may be sized such that providing a single dose of a vapor contained within the vapor accumulation volume to one of the semiconductor processing chambers during semiconductor processing operations conducted in the one or more semiconductor processing chambers does not affect the ability of the vapor accumulator reservoir to simultaneously provide single doses to the other semiconductor processing chambers, wherein each dose represents an amount of vapor normally delivered to one of the semiconductor processing chambers during the performance of semiconductor processing operations.

In some implementations, the apparatus may further include a dilution gas inlet that is in fluidic communication with the vapor accumulation volume and that is configured to be connected with a dilution gas source.

### DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

There are many concepts and implementations described and illustrated herein. While certain features, attributes and advantages of the implementations discussed herein have been described and illustrated, it should be understood that many others, as well as different and/or similar implementations, features, attributes and advantages of the present disclosure, are apparent from the description and illustrations. As such, the below implementations are merely exemplary. They are not intended to be exhaustive or to limit the disclosure to the precise forms, techniques, materials and/or configurations disclosed. Many modifications and variations are possible in light of this disclosure. It is to be understood that other implementations may be utilized and operational changes may be made without departing from the scope of the present disclosure. As such, the scope of the disclosure is not limited solely to the description below because the description of the below implementations has been presented for the purposes of illustration and description.

The present disclosure is neither limited to any single aspect nor implementation, nor to any single combination and/or permutation of such aspects and/or implementations. Moreover, each of the aspects of the present disclosure, and/or implementations thereof, may be employed alone or in combination with one or more of the other aspects and/or implementations thereof. For the sake of brevity, many of those permutations and combinations will not be discussed and/or illustrated separately herein.

Disclosed herein are methods, techniques, systems, and apparatuses for delivering vaporized precursor to one or more semiconductor processing chambers. The concepts disclosed herein may be particularly applicable in cyclic, multi-phase semiconductor processing operations, such as ALD or ALE processes, and may also be well-suited for use in multi-station semiconductor processing tools, i.e., tools where multiple semiconductor wafers may be processed simultaneously in the same chamber or in separate chambers sharing one or more tool subsystems, e.g., a controller, gas distribution system, vacuum pumping system, etc. The concepts disclosed herein may also be implemented in scenarios where there are no cyclic, multi-phase semiconductor processing operations involved and/or in single-station semiconductor processing tools, if desired.

The present inventors recognized that existing semiconductor processing systems, e.g., such as those used to perform ALD operations, may provide undesirable performance in some respects. For example, many ALD systems utilize a mass flow controller (MFC) to control the flow rate of a precursor to semiconductor wafer that is being subjected to ALD processing. However, as noted above, ALD precursor dosing cycles are actually quite short, e.g., on the order of less than a second or generally no more than 2-3 seconds. MFCs, by contrast, have very slow reaction times, e.g., longer than the precursor dosing time. Accordingly, ALD systems that use MFCs to regulate precursor dosing will typically include a divert or shunt valve downstream of the MFC—the precursor flow may thus be delivered either to the processing chamber, where it is flowed across the semiconductor wafer, or diverted into an exhaust system. The flow rate of the precursor through the MFC may be maintained at a relatively steady state, regardless of to which destination the precursor is ultimately delivered. In such systems, the amount of precursor that is delivered to the processing chamber is controlled by actuating the divert valve (which has a much quicker reaction time than the MFC) at times based on the mass flow rate provided by the MFC. This solution, however, is very wasteful, as the precursor must be flowed through the MFC continuously and the precursor that is not delivered to the semiconductor wafer must therefore be diverted into the exhaust system, where it is wasted. MFCs are also expensive components, and in multi-station semiconductor processing tools, each station would require its own MFC and divert valve for such purposes.

The present inventors were involved with development of a multi-station ALD tool that uses pulsed deposition of a low-vapor pressure precursor to the semiconductor wafers being processed in the tool. Such a tool, for example, may utilize a precursor like tungsten pentachloride or tungsten hexachloride, which may be suspended in vaporized form in an inert or otherwise non-reactive carrier gas. Rather than utilize the conventional MFC/divert valve approach, the present inventors recognized that supplying the vaporized precursor to a relatively large vapor accumulator reservoir and then metering out small amounts of vaporized precursor to one or more processing chambers, as needed, would be beneficial. Such a vapor accumulator reservoir may be supplied vaporized precursor from one or more vaporizers via a vapor inlet and be connected to one or more processing chambers by corresponding vapor outlets. It is to be understood that the vapor accumulator reservoirs discussed herein are not to be confused with the working volumes of vaporizers themselves, i.e., where the vaporization of a solid or liquid phase actually takes place (the transition of a solid phase to a gaseous phase is technically referred to as sublimation, but for the purposes of this application, the term “vaporization” or the like are to be understood to refer to the transition of a solid or a liquid phase material into a gaseous phase). A vapor accumulator reservoir, as the term is used herein, refers to a reservoir that receives vapor that is already entrained in a carrier gas but does not, itself, contain a solid- or liquid-phase substance that is to be evaporated. For example, a liquid or solid precursor may be housed in an ampoule with a volume; the precursor may be caused to evaporate within that ampoule volume, thereby creating a vapor—this vapor may then be delivered downstream to the vapor accumulator reservoir by a tube, pipe, or other relatively small cross-sectional flow area conduit (compared to the cross-sectional flow area of the ampoule itself)—the ampoule itself would not be considered to be a vapor accumulator reservoir since it contains the solid or liquid-phase reactant that is to be evaporated. Examples of some vaporizers that may be used in the implementations discussed herein may be found in U.S. Provisional Patent Application No. 62/339,696, which was filed on May 20, 2016, and is hereby incorporated by reference herein in its entirety.

The flow of vaporized precursor from the vapor accumulator reservoir to each individual processing chamber may be regulated by a corresponding valve, which may be actuated so as to deliver very short pulses, e.g., pulse widths of several seconds, 500 ms or less, 50 ms or less, etc., of vaporized precursor to that processing chamber. The volume of the vapor accumulator reservoir may be sized such that it contains enough precursor that providing a single precursor dose from the vapor accumulator reservoir to any one of the processing chambers to which it may be connected does not negatively affect the ability of the vapor accumulator reservoir to simultaneously deliver accurate doses to the other processing chambers to which it is connected (although during processing, such doses may be delivered asynchronously).

In order to maintain the precursor in a vapor state, allow for accurate dosing, and be pressure-compatible with the pressure in the processing chamber, the vapor accumulator reservoir may be held at a relatively low pressure, e.g., a medium vacuum, such as in the 10-15 Torr range (by contrast, the processing chamber may, for example, be held at a pressure of approximately 5 Torr). Thus, the amount of gas (both vaporized precursor and carrier gas) that is resident in the vapor accumulator reservoir may be quite volumetrically dilute. The present inventors recognized that the concentration of the precursor within the vapor accumulator reservoir could be effectively measured by including one or more optical beam ports in the vapor accumulator reservoir and using an optical vapor concentration sensor that includes a beam emitter and a photosensor to project an optical beam into the vapor accumulator reservoir. The optical beam may pass through the vaporized precursor in the vapor accumulator reservoir one or more times before being received by the photosensor. The amount of attenuation of the optical beam, as measured by the photosensor, may then be used to determine the concentration of vaporized precursor that is present in the vapor accumulator reservoir. The optical beam spectrum may be selected such that the optical beam is absorbed by the precursor or reactant vapor but is not absorbed (or is absorbed to a much lesser extent) by the carrier gas. In a tungsten hexachloride or tungsten pentachloride vapor system, for example, the optical beam may be primarily composed of ultraviolet light since the ultraviolet wavelengths are readily absorbed by tungsten hexachloride or tungsten pentachloride but are not absorbed by argon, which may be used as a carrier gas. If other reactants or precursors are used, then the optical beam may be configured to have a different spectrum, e.g., one that is dominated by infrared wavelengths and/or visible light wavelengths. Due to the low operating pressure in the vapor accumulator reservoir, the vapor and carrier gas may generally diffuse quite rapidly, resulting in a very uniform pressure distribution (and thus vapor concentration) within the vapor accumulator reservoir. Once the vapor concentration within the vapor accumulator reservoir is known, a precise amount of vapor may be delivered to an individual process chamber by opening a valve on the vapor outlet for an appropriate period of time. Such metering may be further assisted by the inclusion of an appropriately-sized metering orifice in the flow path from the vapor accumulator reservoir to the processing chamber, e.g., an orifice sized such that sonic or fully-choked flow develops across it during delivery of the vaporized precursor to the processing chamber.

The inclusion of the vapor concentration sensor may also allow for fine-tuning of the vapor concentration within the vapor accumulator reservoir, e.g., by adding additional carrier gas to the vapor accumulator reservoir to further decrease the vapor concentration—the actual concentration may be monitored in real-time as the additional carrier gas is added, and the additional carrier gas may stop being added when the desired concentration is reached. This may be particularly useful in scenarios where the vaporized reactant is provided from a vaporizer that has little flexibility in terms of the concentration of vapor that is delivered.

The present inventors determined that the use of a vapor accumulator reservoir may also make it easier to use an optical vapor concentration sensor. Optical vapor concentration sensors, as explained above, operate by projecting an optical beam (or beam of light) through a gaseous medium. The amount of attenuation experienced by that optical beam is proportionate to path length of the optical beam through the gaseous medium as well as the concentration of the vapor (and carrier gas) in the gaseous medium. Since very low pressure environments such as the medium-vacuum environment in the vapor accumulator reservoir result in a very low concentration of gases, the amount of attenuation in the optical beam per unit length traversed through the vapor may be quite low-so low that it may be difficult to obtain a satisfactory vapor concentration reading at lower-length beam paths, e.g., such as may be available in systems without a large vapor accumulator reservoir. If a vapor accumulator reservoir is used, however, the vapor accumulator reservoir may provide for a relatively long, unobstructed optical path through the vapor, which may allow for increased amounts of attenuation in the optical beam due to the vapor. This, in turn, makes the resulting vapor concentration measurement more accurate.

The process gases that are introduced into a semiconductor processing chamber during processing operations are generally exhausted from the process chamber by way of one or more vacuum forelines, which may be connected with one or more vacuum pumps. The present inventors recognized that it may also be advantageous to integrate the vapor accumulator reservoir with a vacuum pumping manifold for providing such exhaust functionality. For example, vaporized reactants or precursors, such as tungsten hexachloride or tungsten pentachloride, may deposit on process chamber surfaces or form a film if the temperature of the gas in which they are entrained drops below a certain threshold; this holds true for such reactants within the vapor accumulator reservoir, within the process chamber, and within the exhaust system. In order to prevent or mitigate the possibility of such condensation or deposition, the vapor accumulator reservoir and/or the gas supply lines through which the vapor may travel to or from the vapor accumulator reservoir may be heated with one or more heating jackets, e.g., molded or flexible heaters having resistive heating elements embedded within. The present inventors recognized by integrating a portion or portions of the vacuum pumping system, such as a vacuum pumping manifold, into the same structure as the vapor accumulator reservoir, both the vapor accumulator reservoir and the portion or portions of the vacuum pumping system could be heated by the same heating jacket or jackets, thereby preventing or mitigating the potential for condensation or deposition in two completely different stages of reactant flow, i.e., reactants that are both upstream and downstream of the process chamber, using a common heating system.

The concept discussed above is described in more detail with reference to various accompanying Figures below; while these Figures may only depict one or two particular implementations in detail, it is to be understood that the concepts disclosed herein are not limited to these depicted implementations.

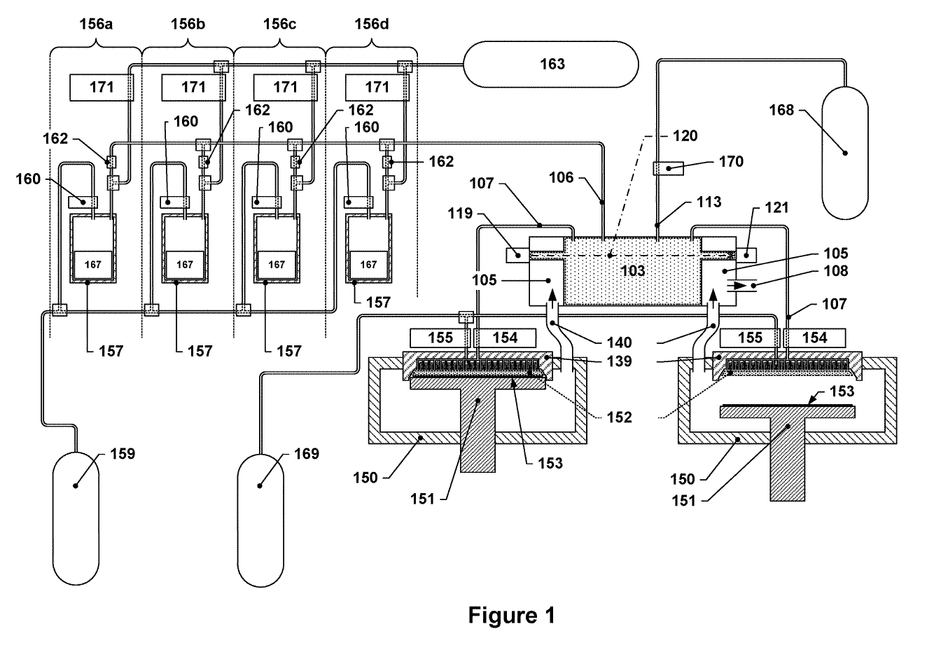

FIG. 1 depicts a high-level schematic of a semiconductor processing tool that incorporates a vapor accumulator reservoir. The semiconductor processing tool of FIG. 1 is a multi-station ALD-type tool. In FIG. 1, two semiconductor processing chambers (also potentially referred to herein as “reactors,” “reaction chambers,” or “process chambers”) 150 are shown—each process chamber 150 may include a pedestal 151 that supports a semiconductor wafer 153 during semiconductor processing operations. The pedestal 151 may be movable between multiple vertical elevations in order to facilitate loading/unloading or processing of the semiconductor wafer 153; the pedestal 151 in the rightmost process chamber 150 is in a lowered position, whereas the pedestal 151 in the leftmost process chamber 150 is in a raised position.

Each process chamber 150 may include a chamber lid 139 that may include a plurality of gas distribution passages that distribute process gases across the semiconductor wafer 153. In this example, each chamber lid 139 includes two sets of separate gas distribution passages, each one for distributing a different precursor gas. This prevents one precursor from mixing with the residue of the other precursor, as would occur if both precursors were to be flowed through the same passages—such mixing may result in chemical reactions occurring in locations other than on the semiconductor wafer 153, which may be undesirable. In some implementations, the gas distribution passages may be in a structure that is separate from the chamber lid 139; it is to be understood that the concepts described herein may be utilized with either type of chamber lid 139 or gas distributor.

In systems such as ALD or ALE processing tools, a “microvolume” 152 may be formed within the process chamber during semiconductor processing operations. The microvolume 152 is formed between the pedestal 151 and the chamber lid 139/gas distributor when the pedestal 151 is in the position required for wafer processing; the chamber lid 139 or gas distributor may also have an annular wall that extends downward around the outer circumference of the pedestal 151, thereby defining a circumferential boundary to the microvolume. The microvolume is much smaller in volume than the overall volume of the process chamber 150, thereby allowing a smaller amount of precursor to be used—this allows for quicker dose delivery, quicker purges, less reactant waste, and various other benefits. The microvolume 152 may be thought of as the contiguous volume in between the surface through which gas is distributed across the semiconductor wafer 153 and the pedestal 151, and may terminate at the first major flow restriction beyond where the semiconductor wafer 153 is supported (where the first major flow restriction refers to a flow restriction large enough to prevent backflow of process gases into the microvolume during normal semiconductor processing operations).

Process gases may be evacuated from the process chambers 150 by way of vacuum forelines 140. The vacuum forelines 140 may be in fluidic communication with a vacuum pumping plenum volume 105 via separate vacuum inlet ports. In the depicted implementation, the vacuum pumping plenum volume 105 encircles a vapor accumulation volume 103.

The chamber lids 139 may each be supplied a first process gas containing a vapor from the vapor accumulation volume 103. The first process gas may be supplied to each process chamber 150 from the vapor accumulation volume 103 by way of a corresponding vapor outlet 107. The flow of the first process gas through each vapor outlet 107 may be controlled by a corresponding first process gas dose valve 154 (or control valve assembly), which may also include a flow restrictor, as discussed earlier, such that fluid flow through the that vapor outlet 107 is restricted to fully choked or sonic flow across the restrictor. Alternatively, the flow restrictor may be located elsewhere on the vapor outlet 107.

As mentioned earlier, the vapor accumulation volume may have a volume that is sufficiently large enough to allow each process chamber to be supplied with a single dose of vapor without affecting the ability of the vapor accumulator reservoir to provide single doses to the other process chambers. In some implementations, the volume vapor accumulation volume may be defined to satisfy the relationship:

$${V}_{p} > \frac{100 {nP}_{c} {V}_{m} q}{20 ( {P}_{p} - {P}_{c} )}$$

where n=number of semiconductor processing chambers serviced by the vapor accumulator reservoir, Pc=average pressure in the microvolumes of those semiconductor processing chambers during atomic layer deposition operations, Vm=microvolume volume of each semiconductor processing chamber (assuming all semiconductor processing chambers are similarly designed), q=the number of microvolumes' worth of vapor delivered to a processing chamber's microvolume during a single dose, and Pp=peak pressure in the vapor accumulator reservoir during pulse delivery to a semiconductor processing chamber. Many of these parameters may vary depending on the particulars of the semiconductor manufacturing process that the vapor accumulator reservoir is intended to support, and vapor accumulation reservoirs may thus vary in size depending on those parameters.

The chamber lids may also each be supplied a second process gas, such as hydrogen, from a second process gas source 169, as well as other gases, such as a chemically inert purge gas (not shown, although may be delivered using a system similar to that used for the second process gas). The flow of the second process gas into each chamber lid 139 may be controlled by a corresponding second process gas dose valve 155.

As can be seen, the vapor accumulation volume 103 may have an optical beam 120 that is emitted by a beam emitter 119. The optical beam 120 may transit the vapor accumulation volume 103 and be received by a photosensor 121, thereby forming a vapor concentration sensor, which may measure the amount of attenuation in the optical beam 120 due to the vapor concentration in the vapor accumulation volume 103 and thereby allow determination of the vapor concentration in the vapor accumulation volume 103.

The vapor accumulation volume may, in some implementations and as discussed earlier, be in fluidic communication with a dilution gas inlet 113 that is connected with a reservoir dilution gas source 168. Flow of dilution gas through the dilution gas inlet 113 may be controlled, for example, by a reservoir dilution gas valve 170 or other suitable control device. The dilution gas may be added, if desired, to reduce the vapor concentration in the vapor accumulation volume 103, depending on the requirements of the particular semiconductor processing being performed and the vapor concentration readings obtained using the vapor concentration sensor.

The vapor accumulation volume 103 may be continuously replenished with vapor supplied from one or more vaporizers 156, such as vaporizers 156a/b/c/d. The vaporizers 156a/b/c/d may each include an ampoule 157 that may contain a reactant 167; carrier gas from a carrier gas source 159 may be selectively provided to each ampoule 157 by way of a corresponding carrier gas flow controller 160, which may control whether carrier gas is supplied to the corresponding ampoule 157 and at what flow rate, if so. As the carrier gas is flowed through one of the ampoules, which may be maintained at a specified pressure and temperature, the reactant 167 may evaporate into the carrier gas and be carried out of the ampoule towards a flow restrictor 162. Prior to reaching the flow restrictor 162, the reactant vapor and carrier gas mixture may be augmented by additional carrier gas supplied from an ampoule dilution gas source 163; the additional carrier gas flow for each ampoule 157 may be regulated by a corresponding ampoule dilution gas flow controller 171. This combined flow of carrier gas and vapor may then pass through the flow restrictor 162, which may be sized to induce sonic flow in the carrier gas/vapor flow during normal operating conditions involved with semiconductor processing operations. Such sonic flow may serve as a buffer that is immune to pressure fluctuations, even if relatively minute (such as on the order of 1 to 5 Torr), in the vapor accumulator reservoir from affecting the pressure environment in the ampoules 157. It is to be understood that other types of vaporizers may be used with the vapor accumulator reservoir as well—the functionality provided by the vapor accumulator reservoir is not dependent on the type of vaporizer used. Other schemes with fewer ampoule dilution gas flow controllers 171 may also be used, e.g., one ampoule dilution gas flow controller 171 may be used to control the flow of dilution gas to multiple ampoules 157.

FIG. 2 depicts an example of a vapor accumulator reservoir as discussed herein. As can be seen in FIG. 2, the vapor accumulator reservoir may be part of an apparatus 201 which may have one or more vapor outlets 207, a vapor inlet 206, a vapor pressure port 210, and divert port 212 that are all in fluidic communication with the vapor accumulation volume of the vapor accumulator reservoir (some of these ports/inlets/outlets may be optional, e.g., the vapor pressure port, vacuum pressure port, etc.—although such interfaces may allow for monitoring sensors or other function-enhancing equipment to be used to better control the operation of the reservoir). In this particular implementation, the apparatus also includes a vacuum pumping manifold that has have a vacuum pumping plenum volume that is in fluidic communication with a vacuum outlet port 208, as well as with a vacuum pressure port 211. In FIG. 2, the vapor accumulator reservoir and the vacuum pumping manifold are not directly visible, as a heating jacket 224 encases the vapor accumulator reservoir and the vacuum pumping manifold. The heating jacket 224 may have one or more heating jacket portions 225 that may be assembled into the heating jacket 224; each heating jacket portion may be adjacent to a wall of the apparatus.

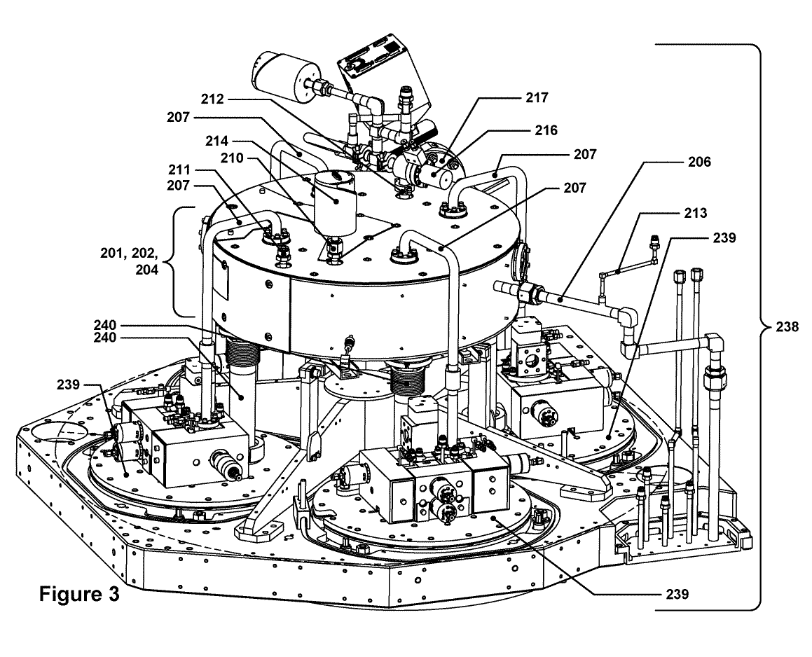

FIG. 3 depicts the vapor accumulator reservoir of FIG. 2 as it may be positioned in a semiconductor processing tool, although with most of the heating jacket and various other components absent. The depicted semiconductor processing tool 238 is not shown in its entirety—for example, the process chambers are not shown, but chamber lids 239 are depicted. In this particular example, the semiconductor processing tool 238 includes four process chambers, although fewer or greater numbers of process chambers may be included in such a tool and serviced by the same vapor accumulator reservoir.

As can be seen in FIG. 3, the apparatus 201 is positioned over the chamber lids 239. The apparatus 201, in this implementation, includes a vapor accumulator reservoir 202 and a vacuum pumping manifold 204. The vacuum pumping manifold 204 may have a vacuum pumping plenum volume that is in fluidic communication with each of the process chambers via vacuum forelines 240, which are connected to chamber lids 239. The vacuum pumping manifold 204 may be in fluidic communication with a vacuum outlet port (not visible in this view) that may be connected with a vacuum valve 217; the vacuum valve 217 may be a flow conductance valve, e.g., a throttle valve, that allows the vacuum flow to be regulated.

Vapor may be supplied to the vapor accumulator reservoir 202 through vapor inlet 206 and then supplied to each chamber lid 239 via the vapor outlets 207. As noted earlier, the vapor in the vapor accumulator reservoir 202 may be diluted by adding a dilution gas, which may be the same type of gas as the carrier gas that carries the vapor from the vaporizers. Such a dilution gas may be introduced directly into the vapor accumulator reservoir or may, as shown, be supplied from a dilution gas inlet 213 that tees into the vapor inlet 206 (this latter option may promote better mixing of the dilution gas and the vapor). The vapor inlet 206 may, as discussed earlier, be supplied with gas from one or more vaporizers (not shown).

The vapor pressure port 210 and the vacuum pressure port 211 may be connected to pressure sensors, such as pressure sensor 214 (the vacuum pressure port 211 may also be connected to a similar sensor, which is not shown here), to allow the pressure conditions within the vapor accumulator reservoir 202 and the vacuum pumping manifold 204 to be monitored.

The vapor accumulator reservoir 202 may, in some implementations, be equipped with a divert port 212 that may be connected to a divert valve 216, which may be used to divert excess vapor from the vapor accumulator reservoir 202 into the vacuum pumping manifold 204 or other location that is part of the exhaust system of the semiconductor processing tool 238.

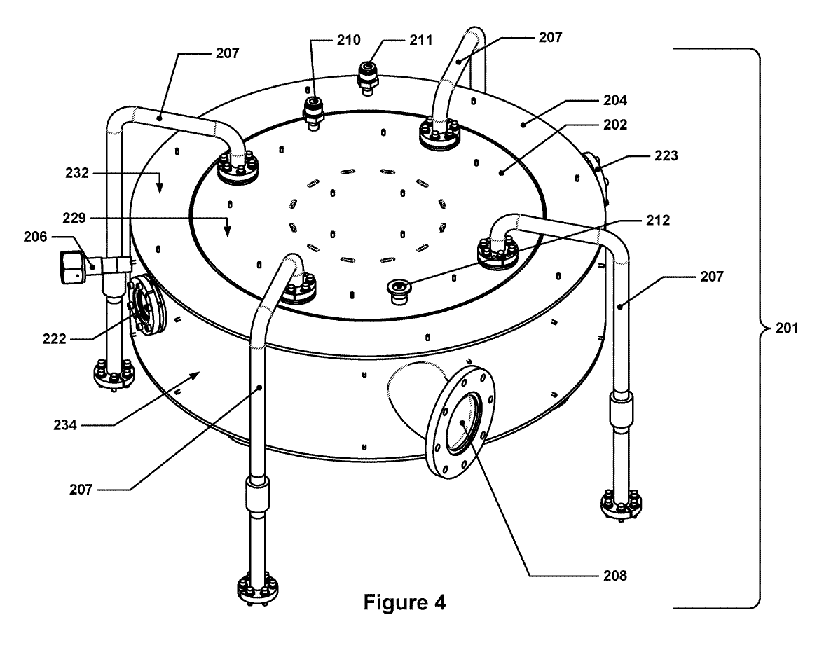

FIG. 4 depicts another view of the apparatus 201. In FIG. 4, the vapor accumulator reservoir 202 and the vacuum pumping manifold 204 are visible. Also visible are a first optical beam port 222 and a second optical beam port 223, which may include windows made of quartz or other transparent material that allows the optical beam mentioned earlier to be projected through the vapor accumulator reservoir.

The vacuum pumping manifold 204 may, as shown, have an overall annular shape and may be in fluidic communication with a vacuum outlet port 208. The vapor accumulator reservoir 202 may be substantially circular in shape, as shown. It is to be understood that other shapes and configurations of the vapor accumulator reservoir 202 and the vacuum pumping manifold 204, if included, may be used as well.

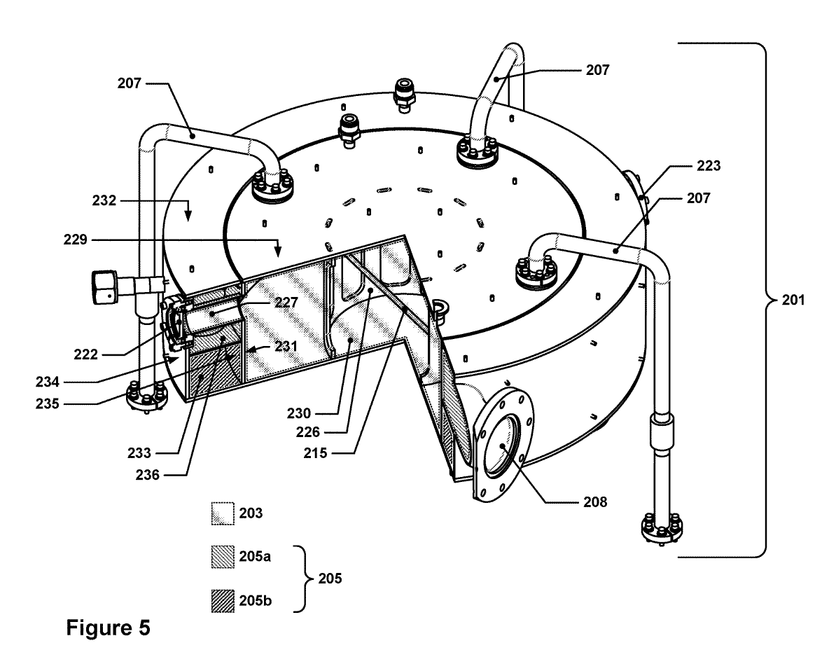

FIG. 5 depicts a cutaway view of the apparatus 201. As can be seen, the vapor accumulator reservoir 202 may include a vapor accumulation volume 203 that is defined, at least in part, by a corresponding upper wall 229, lower wall 230, and outer wall 231. Similarly, the vacuum pumping manifold 204 may include a vacuum pumping plenum volume 205 that is defined, at least in part, by a corresponding upper wall 232, lower wall 233, outer wall 234, and inner wall 235. In this implementation, in which the vacuum pumping manifold 204 is substantially annular in shape, the inner wall 235 of the vacuum pumping manifold 204 and the outer wall 231 of the vapor accumulator reservoir 202 may be provided by the same structure/wall, as may be the case with other walls discussed above, e.g., upper and lower walls.

As can be seen, the vapor accumulator reservoir 202 may optionally include a first optical tunnel 227 that transits through the vacuum pumping plenum volume 205 and that terminates at the first optical beam port 222. Also visible in the vapor accumulator reservoir 202 is a support column 226, which, in this implementation, is provided by a circular tube with multiple cutouts to allow for free flow of vapor through the support column, as well as to allow the optical beam to transit through the support column 226. A temperature sensor 215 and a vapor pressure port 210 may also be included to monitor the temperature and pressure inside of the vapor accumulation volume. By using the optical sensor to determine the density of vaporized reactant within the vapor accumulation volume, and the pressure and temperature sensor to determine the total amount of gas within the vapor accumulation volume (both vapor and carrier gas), the ratio of carrier gas to vapor may be determined and monitored.

The vacuum pumping plenum volume 205 may also include a partition wall 236 that divides the vacuum pumping plenum volume into an upper portion 205a and a lower portion 205b; the partition wall may, in some respects, be thought of as a form of baffle.

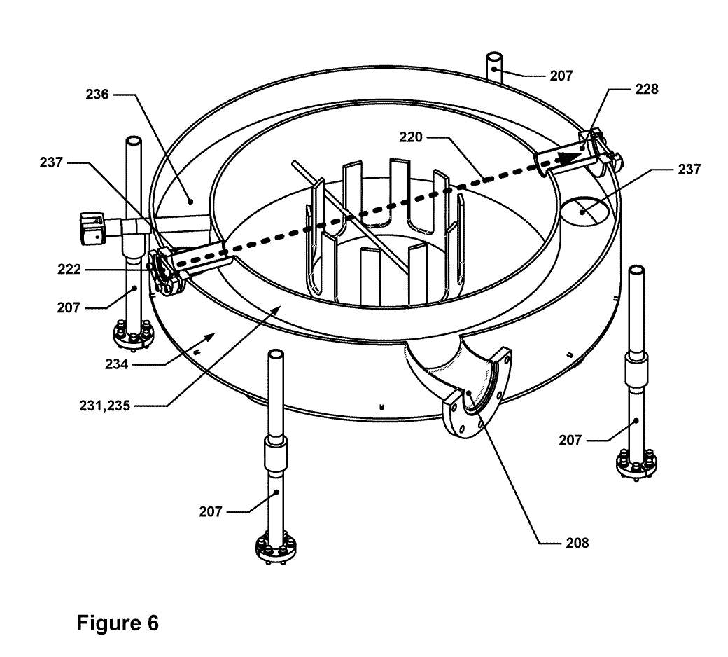

FIG. 6 depicts another cutaway view of the apparatus 201. In FIG. 6, the annular nature of the vacuum pumping plenum volume 205 can be clearly seen. Also shown is the optical beam 220, which traverses the vapor accumulation volume 203 as it transits from the first optical beam port 222 to the second optical beam port 223, passing through the first optical tunnel 227 and a second optical tunnel 228; the optical tunnels act to further increase the path length that the optical beam may transit as it passes through the vapor accumulation volume (in this case, the optical tunnels increase the optical beam transit length by approximately 25% as compared to an implementation where the optical beam ports 222/23 were located at the outer wall 231 of the vapor accumulator reservoir 202 instead of at the end of optical tunnels 227/28). In some implementations, a reflector may be positioned within the vapor accumulation volume opposite the first optical beam port 222 such that the optical beam 220 may be reflected back through the first optical beam port 222; in such implementations, the beam emitter may be collocated with the photosensor so as to detect the reflected optical beam 220. This may allow the optical beam 220 to pass through the vacuum pumping plenum volume 205 twice before reaching the photosensor, thereby further increasing the sensitivity of the optical vapor concentration sensor. In some such implementations, the second optical beam port 223 may be included as well, and the reflector positioned outside of the vapor accumulation volume 203 behind the second optical beam port 223.

Also visible in FIG. 6 is the partition wall 236, which may include two partition openings 237; the partition openings may each, for example, be single openings or may each include multiple openings clustered together, e.g., a circular array of multiple small openings. Thus, each partition opening location may include a set of one or more partition openings 237. Each set of one or more partition openings 237 may be positioned equidistant from the vacuum outlet port 208 such that the flow resistance between each set of one or more partition openings 237 and the vacuum outlet port 208 is generally balanced.

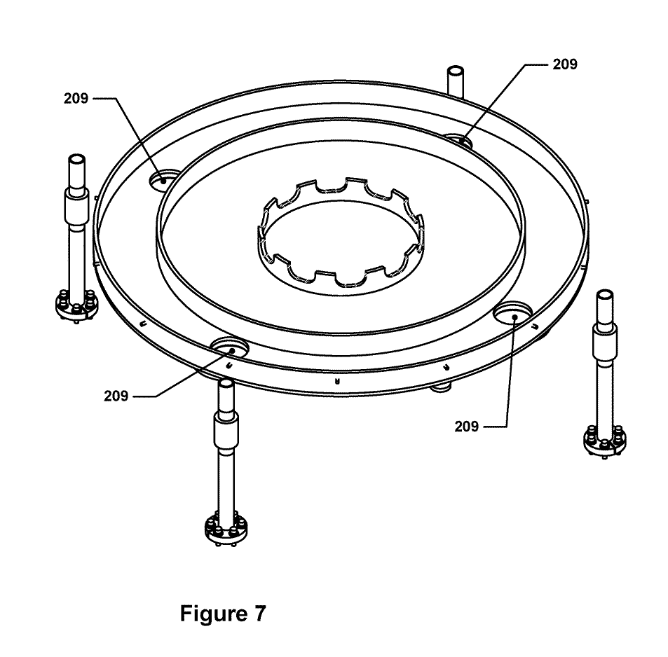

FIG. 7 depicts a further cutaway of the apparatus 201. As can be seen in this cutaway, the lower portion of the vacuum pumping plenum volume 205 may include vacuum inlet ports 209 that may each be in fluidic communication with one of the vacuum forelines 240. The vacuum inlet ports 209 may be arranged in pairs, with the vacuum inlet ports 209 in each pair spaced equidistantly from one of the sets of one or more partition openings 237. Thus, the flow path length between each of the vacuum inlet ports 209 and the vacuum outlet port 208 may generally be the same length and have similar flow resistance.

Unless the context of this disclosure clearly requires otherwise, throughout the description and the embodiments, the words “comprise,” “comprising,” and the like are to be construed in an inclusive sense as opposed to an exclusive or exhaustive sense; that is to say, in a sense of “including, but not limited to.” Words using the singular or plural number also generally include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list, and any combination of the items in the list. The term “implementation” refers to implementations of techniques and methods described herein, as well as to physical objects that embody the structures and/or incorporate the techniques and/or methods described herein. Unless otherwise specified, the term “substantially” refers to within +/−5% of the value indicated. For example, “substantially parallel” means+/−5% of the angular range between 0° and 90°.

What is claimed is:

1. An apparatus for use in a semiconductor processing tool, the apparatus comprising:
a vapor accumulator reservoir having a vapor accumulation volume;
a vapor inlet in fluidic communication with the vapor accumulation volume;
one or more vapor outlets, each vapor outlet in fluidic communication with the vapor accumulation volume;
a first optical beam port, the first optical beam port providing an optical path into the vapor accumulation volume; and
an optical vapor concentration sensor, the optical vapor concentration sensor configured to direct a beam of light through the first optical beam port and through the vapor accumulation volume.

2. The apparatus of claim 1, further comprising:
a second optical beam port located on an opposite side of the vapor accumulator reservoir from the first optical beam port, wherein the optical vapor concentration sensor includes a beam emitter positioned so as to project the beam of light through the first optical beam port and a photosensor positioned so as to receive the beam of light via the second optical beam port.

3. The apparatus of claim 1, wherein the beam of light is predominantly comprised of light in the ultraviolet spectrum.

4. The apparatus of claim 1, further comprising:
one or more vaporizers in fluidic communication with the vapor inlet; and
a sonic flow orifice interposed between the vapor inlet and the one or more vaporizers, wherein the sonic flow orifice is sized so as to develop choked flow during semiconductor processing operations performed using the apparatus.

5. The apparatus of claim 1, further comprising:
a dilution gas inlet, the dilution gas inlet configured to be connected with a dilution gas source that is chemically non-reactive with vapors that are contained within the vapor accumulator reservoir during normal use.

6. The apparatus of claim 1, further comprising:
a vacuum pumping manifold, the vacuum pumping manifold including a vacuum pumping plenum volume that at least partially encircles the majority of the vapor accumulation volume;
one or more vacuum inlet ports, each vacuum inlet port in fluidic communication with the vacuum pumping plenum volume; and
a vacuum output port, the vacuum outlet port in fluidic communication with the vacuum pumping plenum volume.

7. The apparatus of claim 6, wherein:
the vacuum pumping plenum volume is defined, at least in part, by an inner wall and an outer wall, and
the vapor accumulation volume is defined, at least in part, by the inner wall.

8. The apparatus of claim 7, wherein:
the vapor accumulator reservoir is cylindrical in overall shape, and
the vacuum pumping manifold is annular in overall shape.

9. The apparatus of claim 8, wherein:
there are four vacuum inlet ports forming a first set of two vacuum inlet ports and a second set of two vacuum inlet ports,
the vacuum pumping manifold has an annular partition wall that divides the vacuum pumping plenum volume into an upper annular pumping plenum volume and a lower annular pumping plenum volume,
the annular partition wall is interposed between the vacuum outlet port and the vacuum inlet ports,
the annular partition wall includes two sets of one or more partition openings,
each set of one or more partition openings is located equidistant from the vacuum outlet port,
each vacuum inlet port in the first set of inlet vacuum ports is located equidistant from one of the sets of one or more partition openings, and
each vacuum inlet port in the second set of inlet vacuum ports is located equidistant from the other set of one or more partition openings.

10. The apparatus of claim 6, further comprising:
a heating jacket, the heating jacket including:
one or more portions adjacent to an upper wall of the vapor accumulator reservoir,
one or more portions adjacent to a lower wall of the vapor accumulator reservoir,
one or more portions adjacent to an upper wall of the vacuum pumping manifold,
one or more portions adjacent to a lower wall of the vacuum pumping manifold, and
one or more portions adjacent to an outer wall of the vacuum pumping manifold, wherein each of the portions include one or more heating elements configured to supply heat to the wall to which that portion is adjacent.

11. The apparatus of claim 7, further comprising a first optical tunnel, wherein the first optical tunnel terminates at the first optical beam port, extends through the vacuum pumping plenum volume, is part of the vapor accumulator reservoir, and is in fluidic communication with the vapor accumulation volume.

12. The apparatus of claim 11, further comprising:
a second optical beam port located on an opposite side of the vapor accumulator reservoir from the first optical beam port; and
a second optical tunnel, wherein the second optical tunnel terminates at the second optical beam port, extends through the vacuum pumping plenum volume, is part of the vapor accumulator reservoir, and is in fluidic communication with the vapor accumulation volume, wherein the optical vapor concentration sensor includes a beam emitter positioned so as to project the beam of light through the first optical beam port and a photosensor positioned so as to receive the beam of light via the second optical beam port.

13. The apparatus of claim 1, further comprising:
one or more semiconductor processing chambers, each semiconductor processing chamber including a control valve assembly in fluidic communication with one of the vapor outlets, wherein the control valve assembly for each semiconductor processing chamber is configured to regulate vapor flow from the vapor accumulation volume to that semiconductor processing chamber via one of the vapor outlets.

14. The apparatus of claim 13, further comprising:
a carrier gas source; and
one or more ampoules, each ampoule including a solid or liquid precursor and in fluidic communication with the vapor inlet, wherein the carrier gas source is configured to flow carrier gas through each of the one or more ampoules and into the vapor inlet.

15. The apparatus of claim 13, wherein:
each of the one or more semiconductor processing chambers is configured for atomic layer deposition and has a microvolume that is formed between a pedestal of that semiconductor processing chamber and a gas distributor of that semiconductor processing chamber during wafer processing operations; and
the vapor accumulation volume has a volume Vₚ that satisfies the relationship:
$${V}_{p} > \frac{100 {nP}_{c} {V}_{m} q}{20 ( {P}_{p} - {P}_{c} )}$$
where: n=number of semiconductor processing chambers served by the vapor accumulator reservoir, P_{c}=average chamber pressure in the microvolumes of those semiconductor processing chambers during atomic layer deposition operations, Vₘ=microvolume volume for each of those semiconductor processing chambers, q=the number of microvolumes' worth of vapor delivered to one of the processing chambers' microvolume during a single vapor dose, and Pₚ=peak pressure in the vapor accumulator reservoir during delivery of a vapor dose to one of the microvolumes.

16. The apparatus of claim 15, further comprising a sonic flow orifice located on the vapor inlet, wherein the sonic flow orifice is sized such that fully choked flow develops through the sonic flow orifice during all phases of atomic layer deposition operations in the one or more semiconductor processing chambers.

17. The apparatus of claim 13, wherein there are multiple semiconductor processing chambers and the vapor accumulation volume is sized such that providing a single dose of a vapor contained within the vapor accumulation volume to one of the semiconductor processing chambers during semiconductor processing operations conducted in the one or more semiconductor processing chambers does not affect the ability of the vapor accumulator reservoir to simultaneously provide single doses to the other semiconductor processing chambers, wherein each dose represents an amount of vapor normally delivered to one of the semiconductor processing chambers during the performance of semiconductor processing operations.

18. The apparatus of claim 1, further comprising:
a dilution gas inlet, wherein the dilution gas inlet is in fluidic communication with the vapor accumulation volume and is configured to be connected with a dilution gas source.
